(19) United States
(12) Patent Application Publication
(10) Pub. No.: US 2009/0078302 A1
(43) Pub. Date: Mar. 26, 2009

(54) Photovoltaic Device and Plant With Selective Concentration of the Incident Radiation

(75) Inventor: Marcello Navanteri, Priolo Gargallo (SR) (IT)

Correspondence Address: HEDMAN & COSTIGAN P.C., 1185 AVENUE OF THE AMERICAS, NEW YORK, NY, 10036, US

(73) Assignee: ERIC RESEARCH S.r.l., PRIOLO GARGALLO (SR) (IT)

(21) Appl. No.: 12/086,273

(22) PCT Filed: Dec. 14, 2006
(86) PCT No.: PCT/IT2006/000850

§ 371 Date: Aug. 19, 2008

(30) Foreign Application Priority Data
Dec. 19, 2005 (IT) RM2005A000635

(51) Int. Cl. H01L 31/042

(52) U.S. Cl. 136/246

(57) ABSTRACT

The invention relates to a photovoltaic device (1) and a corresponding plant, of the kind comprising a plurality of photovoltaic panels (3), for transforming the incident solar radiation in direct electric current, at least one reflecting surface (2) and a reflecting focal element (8) for concentrating the incident solar radiation, positioned on a frame (4) supported by a support (5) having an electromechanical tracking system (7), in azimuth and/or in elevation, of the direction of origin of the solar rays, wherein said reflecting focal element (8) is further provided with shuttering means of the incident radiation on said reflecting focal element (8) and reflected by said reflecting focal element to said photovoltaic panels (3).

The present invention concerns a photovoltaic device with selective concentration of the incident radiation and a plant of which said device is an integral part in repeated modules.

The invention refers to the field of the production of electric energy through the use of the solar radiation as a primary source.

It is known that, at present, the systems of photovoltaic transformation with concentration of the incident radiation represent one of the fields of exploitation of renewable energy that deserves the major attention on a global scale, as far as both the research and the industry are concerned.

The reasons for so much interest on this technology can be referred to the lowering of the total production costs (substantially the cost of the produced kilowatt-hour) due to the combined effect of the increase of the energy produced during the hour of full insolation and of the increase of the number of insolation hours that are useful in practise.

It is evident that these systems show the best advantages if installed in sites characterised by high values of direct solar radiation.

The systems that are known at present can be divided in different categories.

Most of the present photovoltaic applications are characterised by a very simple functioning and geometry of the plant. In practice they are composed of flat panels, directed towards a fixed point and supported in a fixed position by a fixed support surface. Preferably, these panels are directed towards the point of passage of the sun at midday, i.e. towards the point the azimuth of which is located in an intermediate position between the position of the azimuth at dawn and the position of the azimuth at sunset and the height of which is located in an intermediate position between that of the sun at midday at the summer solstice and that of the sun at midday at the winter solstice. In practice, a position is chosen that can be irradiated by the solar rays for the longest time during the day, also looking for minimising the resultant of the incident angles of the solar rays with the surface of the panel during the day. However, more often the position of the panel depends on external factors, such as the facing direction and the angle of a pre-existent architectural or natural element that can conveniently be used as a support for the panel. An example of this kind of plants is constituted by panels covering walls and roofs of buildings.

A second kind of application (especially applied in big production plants) provides for the photovoltaic panels being supported by structures having the possibility of tracking the sun in his path in the sky, simply in azimuth (East-West tracking), and in both azimuth and elevation. The aim of such structures of tracking is obviously that of maximising the amount of produced electric energy, through the maximisation of the incident solar energy resulting from the lining up of the panels with the direction of origin of the solar rays.

Finally, in a further kind of application (up to now in practice applied only in high temperature thermodynamic plants) it is also provided for the solar concentration of the incident rays, i.e. the photovoltaic cell is constituted by an element positioned in correspondence of the focus of one or more concentration mirrors. This solution allows for the achievement of values of concentration of the incident solar radiation equal to hundreds of times the natural value. The high temperatures associated with such values of solar radiation impose for the use of special photovoltaic cells. Such cells, characterised by a high yield of transformation of solar energy in electric energy, are substantially different from the mono or polycrystalline silicium cells commonly available on the market.

It follows that, even if this last kind of application comes out to be much more advantageous than the applications with no concentration of the radiation, on the other side it is difficult to realise and involves high costs.

Finally, it is possible to expose to a concentrated solar radiation even the “traditional” mono or polycrystalline silicium photovoltaic cell obtaining the benefits of higher transformation yields, but a series of technological problems due to the use of the cell at limit condition must be solved before.

In fact, if on one hand this kind of solution allows the photovoltaic cell to work at its optimal irradiation values, on the other hand an excessive concentration, for example during the hours at the middle of the day, could cause the exceeding of electromechanical limits of the same cells, in particular of the higher limit for the functioning temperature and of the limit for the short circuit current.

In order to avoid that this circumstances can happen, this kind of applications should provide for solutions that can avoid the exceeding of these limits, allowing for the system to continuously control the incident solar radiation on the photovoltaic cell: the instantaneous value will be a little lower than the maximum ammissible value for the photovoltaic cell used.

In practice, in order to maximise the yield of the photovoltaic cell during the day, the exposure system should be able to adapt to the variation of the solar irradiation conditions.

In this context is proposed the solution according to the present invention with the aim of providing for an innovative solution for plants allowing for both the tracking of the incident solar radiation on the photovoltaic cell, and its concentration, through a preliminary treatment of the solar radiation before it reaches the photovoltaic cell.

These and other results are achieved according to the present invention by proposing a photovoltaic device and plant constituting a combination of the solutions according to the prior art, and overcoming the drawbacks that such a combination would inevitably cause, through the introduction of control and transformation devices of the solar radiation collected and concentrated on the photovoltaic cell.

More in particular, the device according to the present invention provides for the following subsequent steps of transformation of the solar radiation: an electromechanical system for the tracking of the direction of origin of the solar rays, a system made of reflectors/concentrators for the reflection and the optical treatment of the collected solar radiation, a plurality of photovoltaic panels on cells made of a semiconductive material, such as silicium, for transforming the incident solar radiation in direct electric current, a solid state inverter for transforming the direct electric power in low voltage alternate electric power (380 volt, 50 hz), transformers, protection members and measurement instruments for the controlled transfer of the produced electric energy to the distribution network.

It is therefore a first specific object of the present invention a photovoltaic device of the kind comprising a plurality of photovoltaic panels, for transforming the incident solar radiation in direct electric current, at least one reflecting surface and a reflecting focal element for concentrating the incident solar radiation, positioned on a frame supported by a support having an electromechanical tracking system (7), in azimuth and/or in elevation, of the direction of origin of the solar rays, wherein said reflecting focal element is further provided with shuttering means of the incident radiation reflected towards said photovoltaic panels.

Preferably, according to the present invention, said shuttering means of the incident radiation can be constituted by one or more surfaces of said reflecting focal element, provided with different degrees of opacity to the solar radiation and/or with different features of transparency to different wavelengths of the solar radiation, constituting areas having a different degree of opacity and/or reflection, said reflecting focal element being able to be rotated so to expose to the incident radiation from time to time an area having different degree of opacity and/or reflection according to needs.

Preferably, according to the invention, said areas having a different degree of opacity and/or reflection are realised by means of application of coatings based on aluminium and/or metal oxides on said reflecting focal element, optionally supported on films made of plastic material.

In particular, according to the present invention, said areas having a different degree of opacity and/or reflection have different degree of filtration of radiations the wavelength of which is comprised between 0.4 and 0.8 nm.

Such coating layer allows therefore, depending on the metal deposition parameters, not only a higher or lower degree of passage of visible light, but also a higher or lower degree of reflection of U.V. or infrared radiations.

According to the invention, said reflecting surface is realised by means of an aluminium layer, which underwent a treatment of mechanical polishing before being cold-shaped in its final parabolic form and subsequently covered by a transparent acrylic paint.

Always according to the invention, said reflecting focal element is made of glass.

Preferably, according to the invention, said reflecting focal element is constituted by a prism, each face of which is treated in order to have a different degree of opacity and/or reflection.

More preferably, according to the invention, on each face of said prism a different laminated covering is applied which is constituted by an intermediate layer made of a plastic film, supporting different coatings based on aluminium and/or metal oxides, by an internal adhesive layer for the adhesion with said face and by an external protection layer.

Moreover, according to the present invention, said photovoltaic device further comprises a solid state inverter for transforming the direct electric power in low voltage alternate electric power, transformers, protection members and measurement instruments for the controlled transfer of the produced electric energy to the distribution network.

It is moreover a second specific object of the present invention a photovoltaic plant constituted by one or more photovoltaic devices as previously defined, linked to one another so to form a single circuit, comprising an automatic electronic system for monitoring and controlling.

The present invention will be now described, for illustrative, non limitative purposes, according to one preferred embodiment, in particular with reference to the figures of the enclosed drawings, wherein:

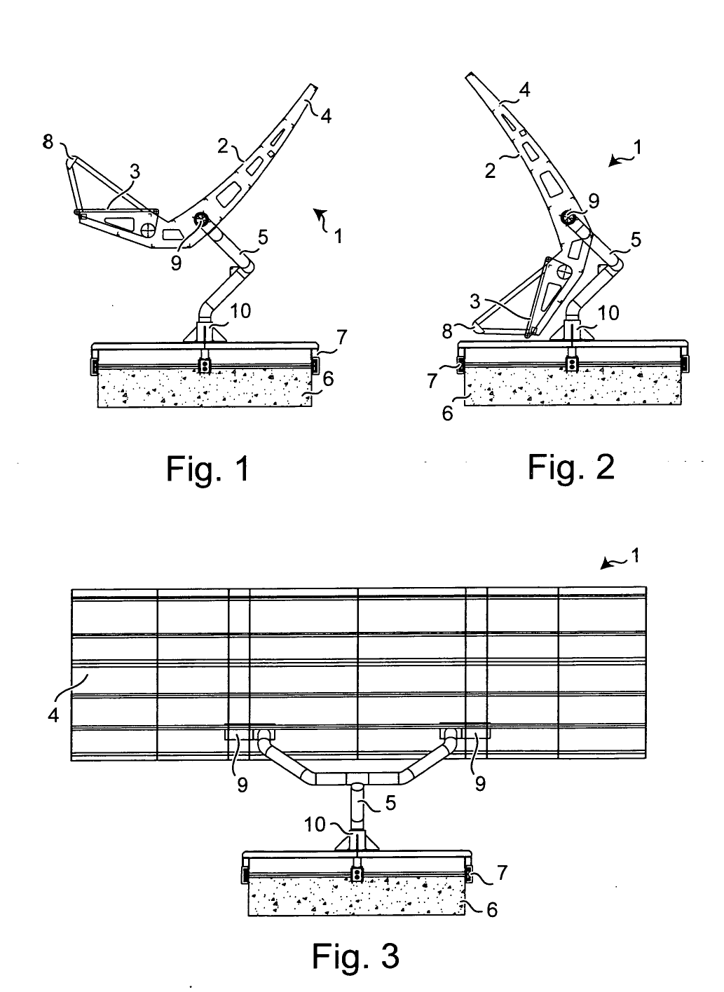

FIG. 1 shows a lateral view of a photovoltaic device according to the present invention, in a position of maximum elevation,

FIG. 2 shows a lateral view of the photovoltaic device of FIG. 1, in a position of minimum elevation,

FIG. 3 shows a rear view of the photovoltaic device of FIG. 1,

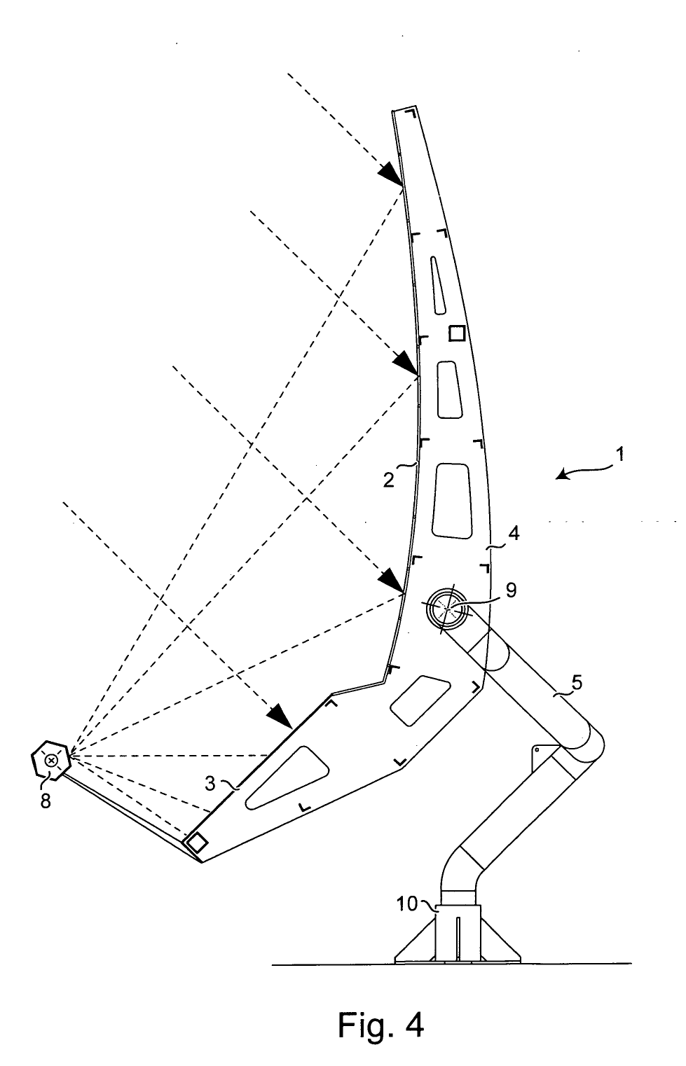

FIG. 4 shows a lateral view of the photovoltaic device of FIG. 1, representing the path of different incident solar rays,

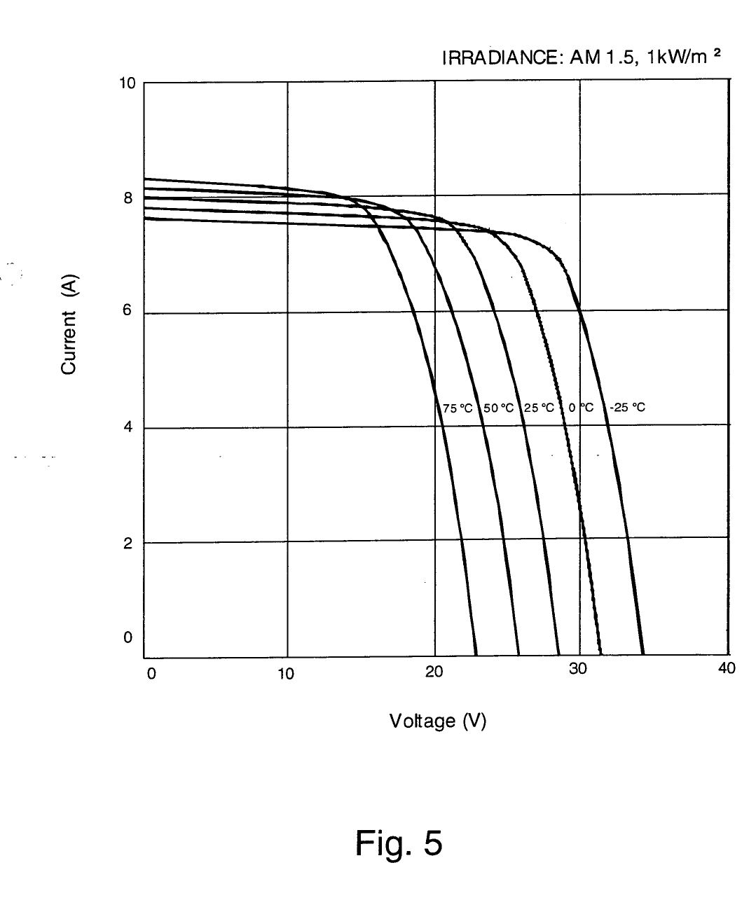

FIG. 5 shows the diagram of the characteristic voltage/current curves of the photovoltaic device of the present invention, as a function of the temperature at a prefixed incident radiation value,

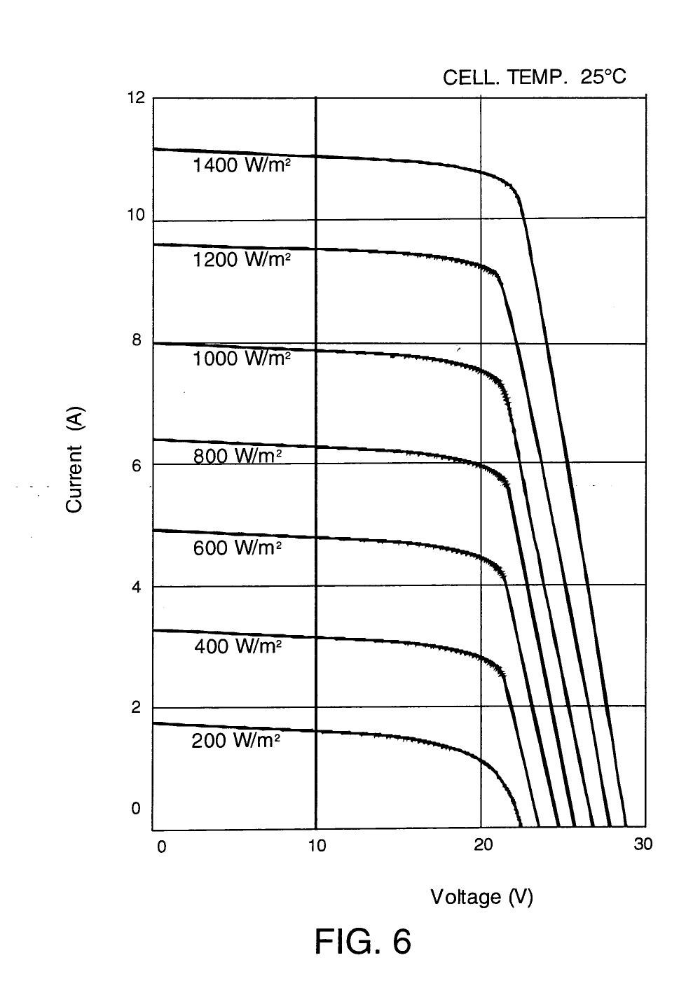

FIG. 6 shows the diagram of the characteristic voltage/current curves as a function of the incident radiation at a prefixed temperature value, and

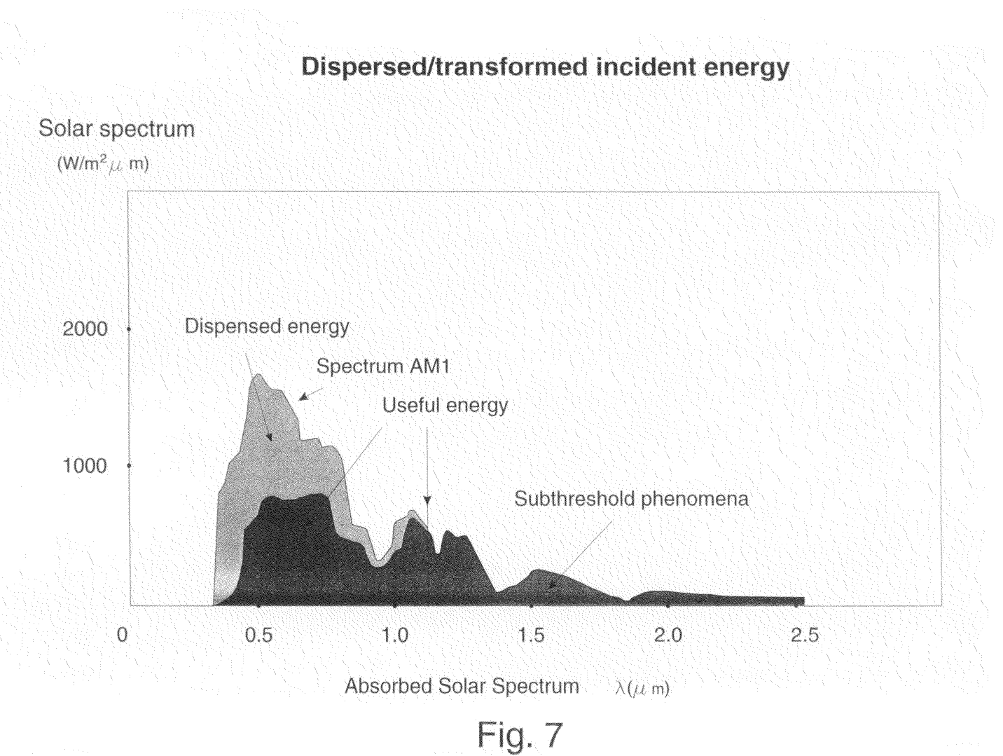

FIG. 7 shows a diagram in which the line of the values of the incident solar radiation as a function of the wavelength is compared with the line of the values of the energy actually transformed by the photovoltaic cell, at fixed wavelength values.

Making reference to FIGS. 1-4, the photovoltaic device according to the present invention is referenced as a whole by the reference number 1 and is constituted by a reflecting surface 2 and by a plurality of photovoltaic panels 3, positioned on a frame 4 supported by a support 5 laying upon a base 6 provided with an electromechanical system 7 for tracking the direction of origin of the solar rays. The photovoltaic device 1 also comprises a reflecting focal element 8, having the task of collecting the radiation reflected by the reflecting surface 2, subject it to an appropriate optical treatment, shown in a better detail after in the description, and direct it to photovoltaic panels 3 for transforming the incident solar radiation in direct electric current. The device further comprises other devices that are necessary for its functioning and not shown, in particular a solid state inverter for transforming the direct electric power in low voltage alternate electric power (380 volt, 50 hz), transformers, protection members and measurement instruments for the controlled transfer of the produced electric energy to the distribution network.

A plant according to the present invention is constituted by one or more photovoltaic devices 1 linked to one another so to form a single circuit.

The whole plant can be monitored and controlled by an automatic supervision system.

Analysing in particular the different components of the device of the present invention, the electromechanical system 7 for tracking the direction of origin of the solar rays allows to orientate the frame 4 and therefore the reflecting surface 2 and the photovoltaic panels 3 of the device 1 both in azimuth and in elevation. The movement is supplied by electromechanical actuators controlled by a local programmable logic controller (PLC). The reference signal is stored in the memory of the PLC.

Moreover, according to the signals revealed by appropriate vibration sensors, the electromechanical system 7 is able to place the device in a security position when the speed of the wind exceeds a prefixed threshold.

The frame 4 is rigid and, for instance, can be constituted by tubes welded to one another. In such a case, a very good way of realising the whole body can be achieved by means of inert atmosphere continuous wire submerged arc welding. Such a kind of welding ensures both for the predictability of the mechanic efficiency of the welded joints (Z=1) and for the respect of the dimensional tolerance limits provided for the geometrical nominal values.

It is moreover a good rule that the finished structure is subjected to a protective painting cycle. For instance, the structure of the frame 4 can be subjected to a cycle providing for: sandblasting with compressed air Sa 2½ grade according to standard ISO 8501-1:1988, having sandblasting profile of 25-30 μm, application of a coat of an anticorrosion primer (such as ethylsilicate enriched with zinc), in order to obtain a final thickness of dry film of at least 75 μm, subsequent application of a coat of a chlororubber paint, in order to form a second intermediate layer that, in a dry state, has a final thickness of at least 40 μm. Final application of a coat of alkydic modified chlororubber paint, in order to form an external layer having a final dry thickness of at least 40 μm. The final thickness of the dry multilayered film of paint will be therefore equal to at least 155 μm.

The resting of photovoltaic panels 3 on the frame 4 is secured, for instance, by metal elements made of welded profiles, while the support of the reflecting/concentrating elements is represented by shaped centerings.

The constant lining up of the panels with the direction of origin of the solar rays is allowed by the presence on the support 5 of two articulated joints, a first articulated joint 9 having horizontal rotation axis and a second articulated joint 10 having vertical rotation axis.

In particular the articulated joints, both the horizontal axis articulated joint 9 and the vertical axis articulated joint 10, are constituted by pivots built around coaxial sleeves and planar thrust block bearings. The construction material of said sleeves and bearings is teflon loaded with glass fibres. Such a solution was adopted mainly taking account of the quasi-static functioning conditions of the kinematisms. In fact, in case of a complete rotation of 60° in elevation, such a movement must be made in a period of about six hours. By means of an action of pointing every about ten minutes it implies 2.5 sexagesimal degree per each movement and a contact speed of some centimetres per second. The same situation applies for the action of tracking in azimuth: in the case of a total daily average of 150° in a period of ten hours and operation every ten minutes it implies a unitary width of less than 5 sexagesimal degree per each movement.

Said bearings allow to transfer any radial stress, axial stress and overturn moments to the base. Such stresses are those resulting both from the weight of the device and from the action of the wind occasionally hiting the device.

As far as the base 6 is concerned, in order to reduce the impact on the site (in terms of permanent modifications), the kind of foundation chosen according to the preferred embodiment shown with reference to the figures, is a slab made of reinforced concrete.

According to a logic of soil protection, the foundation pad is cast on the soil without any excavation.

Reference being made to the concentration of the incident solar radiation, it was already said that it is obtained by means of a particular reflecting surface 2 having a parabolic bending. The radiation thus obtained is distributed on the photovoltaic cells 3 by a reflecting focal element 8, positioned in a position very close to that of the geometric focus of the parabola constituted by the reflecting surface 2. The reflecting surface 2 presents a parabolic profile with the axis that is parallel with respect to the normal of the surface of the photovoltaic panels, and is integral with the frame 4, in order to be constantly lined up with the direction of the solar rays. The solar radiation is thus concentrated on a reflecting surface positioned nearby the geometric focus of the parabola and from here reflected towards the surface of the photovoltaic panels 3.

The value of the radiation that is reflected and distributed on the photovoltaic cells is more than double than the ambient value (the exact value, according to the preferred embodiment of the device of the present invention, is a concentration ratio of 1:2.3; i.e. 1 m² of photovoltaic cells 3 directly exposed to the sun per 2.3 m² of reflecting surfaces 2 of additional collection). Conclusively, the solar radiation to which the photovoltaic cell is subjected is equal to about three times the instantaneous radiation intensity.

Obviously, such ratios are liable to modifications in order to perfectly adapt the plant to the latitude of the site of installation.

The electric energy produced by the photovoltaic cell proportionally follows the value of the incident solar energy.

In order to achieve the best performance of the device of the present invention, according to the embodiment shown in FIGS. 1-4 the reflecting surface 2 is realised by means of an aluminium layer, which underwent a treatment of mechanical polishing before being cold-shaped in its final parabolic form. The reflecting surface is finally covered with a transparent acrylic paint. The focal element 8 is made of glass on which laminated elements for controlling both the total reflection value and that due to the infrared/visible/UV rates were previously applied.

In corrispondence with the hours of maximum solar irradiation, the combined effect of the direct exposure and the reflected concentrated radiation, can exceed the maximum design operative value of the photovoltaic cell. In this case, the immediate effect would be an increase of the temperature of the silicium cell and the subsequent vertical decrease of the produced electric energy.

In order to avoid this can happen, in the photovoltaic device of the present invention, an automatically operated mechanism provides for the shuttering of the incident solar radiation on the photovoltaic cells 3 through the action of shuttering means. The control signal of the mechanism is triggered by a PLC comparing the data of electric power generated from time to time by a single module with those stored in a matrix residing in a memory and characteristic of the photovoltaic cell used; all il tutto appreciated by means of the instantaneous operative temperature of the photovoltaic cell.

The shuttering means are constituted by a film having different degrees of opacity (i.e. of reflection) of the solar radiation, positioned on the reflecting focal element 8 so to define areas with different reflection degree. By the rotation of the reflecting focal element 8, it interposes along the path of the rays from the parabolic element to the photovoltaic cell a surface with variable reflection that determines the quantity and quality of the incident solar radiation on the photovoltaic cell. In this way, even when the solar radiation reaches values that, lacking a partial shading, would exceed the operating threshold of the photovoltaic cell, the value of the solar radiation actually incident on the photovoltaic cell is stopped at the design upper limit (in the case of the shown embodiment, a set up value of 1.489 watt/m²).

The threshold operative value of the cell embedded in the photovoltaic device according to the present invention is considerably greater than that normally declared by photovoltaic cells producers (i.e. 1.000 watt/m² of nominal irradiation). According to the present invention, in fact, the photovoltaic cell is able to regularly operate at an irradiation of 1.400 watt/m², provided that its temperature is contained below the threshold operative temperature of the cell.

FIG. 5 shows the characteristic voltage/current curves expected as a function of the temperature at a prefixed value of incident radiation. It is evident that the increase of operative temperature of the photovoltaic cell implies a reduction of the voltage at the terminals.

FIG. 6 shows the characteristic voltage/current curves as a function of the incident radiation at a prefixed value of temperature. The diagram shows how an increase of the irradiation of the photovoltaic cell implies an increase of the current supplied at the terminals.

The trend of the characteristic curves thus explains the convenience of exposing the photovoltaic cell to the maximum possible value of irradiation, compatibly with its electromechanical limits, that can be summarised substantially by the two design threshold of the operative temperature and the short circuit current.

The shuttering means of the incident solar radiation on the photovoltaic cell have, according to the present invention, still another prerogative: that of having different “transparency” features for different wavelength of the light radiation.

This result can be achieved by means of plastic films on which a thin layer of aluminium and metal oxides is applied, the metal oxide being different as far as their typology and concentration is concerned, and allows for the incident solar radiation to be conditioned so to get down the energy content of the range having a wavelength comprised between 0.4 and 0.8 nm.

In fact, it was found that for radiations with wavelength comprised within this range, the ratio of the energy dispersed and the energy transformed by the photovoltaic cell, and therefore useful, is particularly unfavourable, as evident from FIG. 7, showing the curve of the incident solar radiation for any wavelength together with the curve of the energy actually transformed by the photovoltaic cell.

The trends shown by FIG. 7, wherein is also shown a remarkable decreasing of the value of the solar radiation per wavelengths greater than 1.5 nm, can be understood taking account of the involved physical phenomena. In fact, the energy of each single photon can be too low to break the bond between electron and nucleus (spectrum wavelengths greater than 1.5 nm), with the consequence that the incident photon, by means of its action, is not able to make available a free electron at the terminals of the photovoltaic cell; or it can be too high (spectrum wavelengths comprised between 0.4 and 0.8 nm) when the photon energy is sufficient to generate electron-hole couples, thus dispersing as heat the amount of energy exceeding those necessary to make the electron free from the nucleus. In this second case, the heat due to the photons is amongst the causes of the temperature increase of the photovoltaic cell and the consequent loss of efficiency.

The use of a film with selective shading properties is aimed at getting down the energy content of these wavelengths, in order to make the most complete use of the inlet solar energy possible.

The advantages of the photovoltaic device according to the present invention are self evident, in particular as far as the maximisation of the extracted energy is concerned. During the period of greatest irradiation, the combined effect of concentration and selective filter allows the photovoltaic cell to work at its actual top conditions, just below one of the two physical limits of the silicium cell: the temperature of the cell or the maximum tolerated solar radiation taking account of the maximum value of circulating current.

Moreover, due to the high concentration that can be obtained, the device of the invention is particularly efficient in maximising the energy extracted in limited irradiation conditions (cloudy weather).

Further it must be added that the result of the selective action of the filtering film reduces the heating resulting as a consequence of the dissipation of the spectrum bands having higher amounts of energy.

The present invention was described for illustrative non limitative purposes, according to its preferred embodiments, but it has to be understood that any variation and/or modification can be made by the persons skilled in the art without for this reason escaping the scope of protection concerned, as defined by the enclosed claims.

1. Photovoltaic device (1) of the kind comprising at least a photovoltaic panel (3), for transforming the incident solar radiation in direct electric current, at least one reflecting surface (2) and a reflecting focal element (8) for concentrating the incident solar radiation, positioned on a frame (4) supported by a support (5) having an electromechanical tracking system (7), in azimuth and/or in elevation, of the direction of origin of the solar rays, said reflecting focal element (8) being further provided with shuttering means of the incident radiation reflected towards said photovoltaic panels (3), characterized in that said shuttering means of the incident radiation are constituted by one or more surfaces of said reflecting focal element (8), provided with different degrees of opacity to the solar radiation and/or with different features of transparency to different wavelengths of the solar radiation, constituting areas having a different degree of opacity and/or reflection, said reflecting focal element (8) being able to be rotated so to expose to the incident radiation from time to time an area having different degree of opacity and/or reflection according to needs.

2. Photovoltaic device (1) according to claim 1, characterised in that said areas having a different degree of opacity and/or reflection are realised by means of application of coatings based on aluminium and/or metal oxides on said reflecting focal element (8).

3. Photovoltaic device (1) according to claim 2, characterised in that said coatings based on aluminium and/or metal oxides are supported on films made of plastic material.

4. Photovoltaic device (1) according to claim 1, characterised in that said areas having a different degree of opacity and/or reflection have different degree of filtration of radiations the wavelength of which is comprised between 0.4 and 0.8 nm.

5. Photovoltaic device (1) according to claim 1, characterised in that said reflecting surface (2) is realised by means of an aluminium layer, which underwent a treatment of mechanical polishing before being cold-shaped in its final parabolic form.

6. Photovoltaic device (1) according to claim 1, characterised in that said reflecting surface (2) is covered by a transparent acrylic paint.

7. Photovoltaic device (1) according to claim 1, characterised in that said reflecting focal element (8) is made of glass.

8. Photovoltaic device (1) according to claim 1, characterised in that said reflecting focal element (8) is constituted by a prism, each face of which is treated in order to have a different degree of opacity and/or reflection.

9. Photovoltaic device (1) according to claim 8, characterised in that on each face of said prism a different laminated covering is applied which is constituted by an intermediate layer made of a plastic film, supporting different coatings based on aluminium and/or metal oxides, by an internal adhesive layer for the adhesion with said face and by an external protection layer.

10. Photovoltaic device (1) according to claim 1, characterised in that it further comprises a solid state inverter for transforming the direct electric power in low voltage alternate electric power, transformers, protection members and measurement instruments for the controlled transfer of the produced electric energy to the distribution network.

11. Photovoltaic plant constituted by one or more photovoltaic devices as defined in claim 1, linked to one another so to form a single circuit.

12. Photovoltaic plant according to claim 11, characterised in that it comprises an automatic electronic system for monitoring and controlling.
